(19) United States
(12) Patent Application Publication
(10) Pub. No.: US 2026/0247551 A1
(43) Pub. Date: Aug. 20, 2026

(54) WIRING MODULE

(71) Applicant: Yazaki Corporation, Tokyo (JP)

(72) Inventors: Masayoshi Takayanagi, Shizuoka (JP); Sadaharu Okuda, Shizuoka (JP); Hikaru Sano, Shizuoka (JP); Koki Adachi, Shizuoka (JP); Ryoichi Murata, Shizuoka (JP); Takaaki Yuasa, Shizuoka (JP)

(21) Appl. No.: 19/534,305

(22) Filed: Feb. 9, 2026

(30) Foreign Application Priority Data
Feb. 14, 2025 (JP) 2025-022073

(51) Int. Cl. H05K 5/02

(52) U.S. Cl. CPC H05K 5/0247; H05K 5/0221; H05K 5/0226

(57) ABSTRACT

A wiring module includes a wiring module case that has a wiring path provided with a wiring material and a connector that has a housing to which one end of the wiring material is fixed. The wiring module case has a case body provided with the wiring path, and a hinge structure portion that is connected to the case body on the connector side of the case body via a hinge, is rotatably provided around an axis of the hinge between an extended position extending from the case body so as to protrude from a battery module and a bent position approaching the battery module, and has a wiring material fixing portion for fixing the wiring material W on one end side from the wiring path (11a) toward the connector.

### CROSS-REFERENCE TO RELATED APPLICATIONS

The present application claims priority to and incorporates by reference the entire contents of Japanese Patent Application No. 2025-022073 filed in Japan on February 14, 2025.

### BACKGROUND OF THE INVENTION

### 1. Field of the Invention

The present invention relates to a wiring module.

### 2. Description of the Related Art

As an example of a technology relating to a conventional wiring module and connector, Japanese Patent Application Laid-open No. JP 2019 - 192 336 A discloses a wiring module including a flat electric wire attached to a power storage element group in which a plurality of power storage elements are integrated and an electric wire side connector connected to the end of the flat electric wire and fitted into an equipment side connector provided in a control unit of the power storage element group. The flat electric wire has an extra length portion extending from the power storage element group, and a bend restricting plate is laminated on a part of the extra length portion. The bend restricting plate suppresses free movement of the extra length portion due to vibration or the like.

In such a wiring module, for example, the arrangement of the extra length portion of the wiring material may be set in consideration of the arrangement of peripheral components such as a cover of a battery pack, but there is room for further improvement in the arrangement of the extra length portion of the wiring material.

### SUMMARY OF THE INVENTION

The present invention has been made in view of the above circumstances, and an object thereof is to provide a wiring module capable of appropriately arranging an extra length portion of a wiring material.

In order to achieve the above mentioned object, a wiring module according to one aspect of the present invention includes a wiring material that is electrically connected to an electrode terminal of a battery cell constituting a battery module; a wiring module case that has a wiring path provided with the wiring material; and a connector that has a housing to which one end of the wiring material is fixed, wherein the wiring module case has a case body that is provided with the wiring path, and a hinge structure portion that is connected to the case body on the connector side of the case body via a hinge, is rotatably provided around an axis of the hinge between an extended position extending from the case body so as to protrude from the battery module and a bent position approaching the battery module, and has a wiring material fixing portion for fixing the wiring material on the one end side from the wiring path toward the connector.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a front view illustrating a schematic configuration in a state in which a wiring module including a connector according to an embodiment is assembled to a battery module and a hinge structure portion is at an extended position;

FIG. 2 is a plan view of the hinge structure portion as viewed from a P direction in FIG. 1; and

FIG. 3 is a front view illustrating a schematic configuration in a state in which the wiring module including the connector according to the embodiment is assembled to the battery module, the hinge structure portion is at a bent position, and the connector is fitted to a mating connector.

### DETAILED DESCRIPTION OF THE PREFERRED EMBODIMENTS

Hereinafter, an embodiment according to the present invention will be described in detail with reference to the drawings. Furthermore, the present invention is not limited by the embodiment. In addition, components in the following embodiments include those that can be easily replaced by those skilled in the art or those that are substantially the same.

### Embodiment

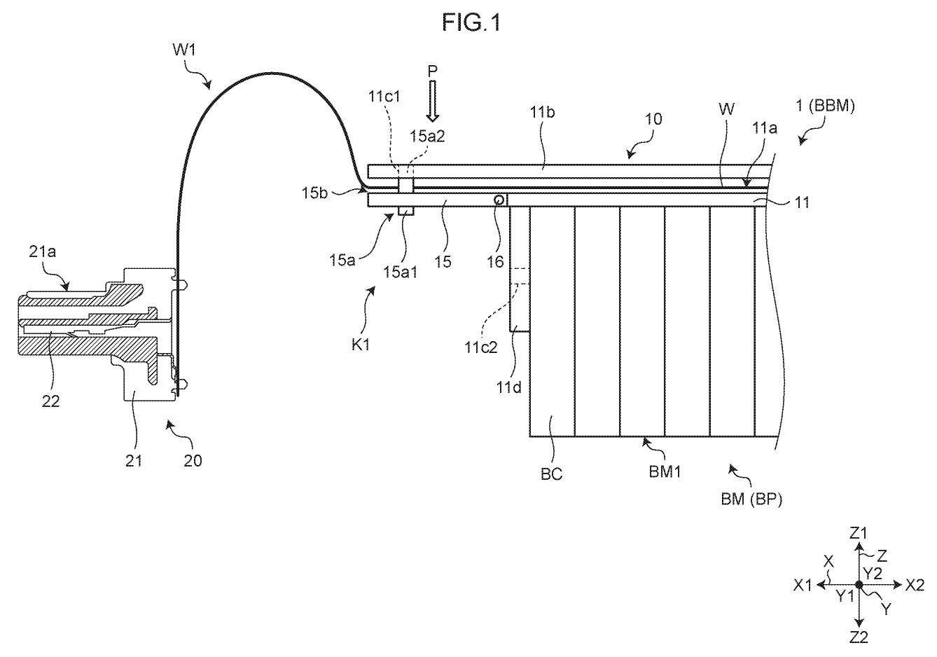

A wiring module 1 of the present embodiment illustrated in FIG. 1 is included in a busbar module BBM assembled to a battery module BM. The wiring module 1 includes a wiring module case 10, a wiring material W, and a connector 20. The plurality of battery cells BC constitute a battery module BM. The battery module BM is a component of the battery pack BP. The battery pack BP may have a plurality of battery modules BM. The battery pack BP is mounted as a power source in a vehicle such as an electric vehicle or a hybrid electric vehicle.

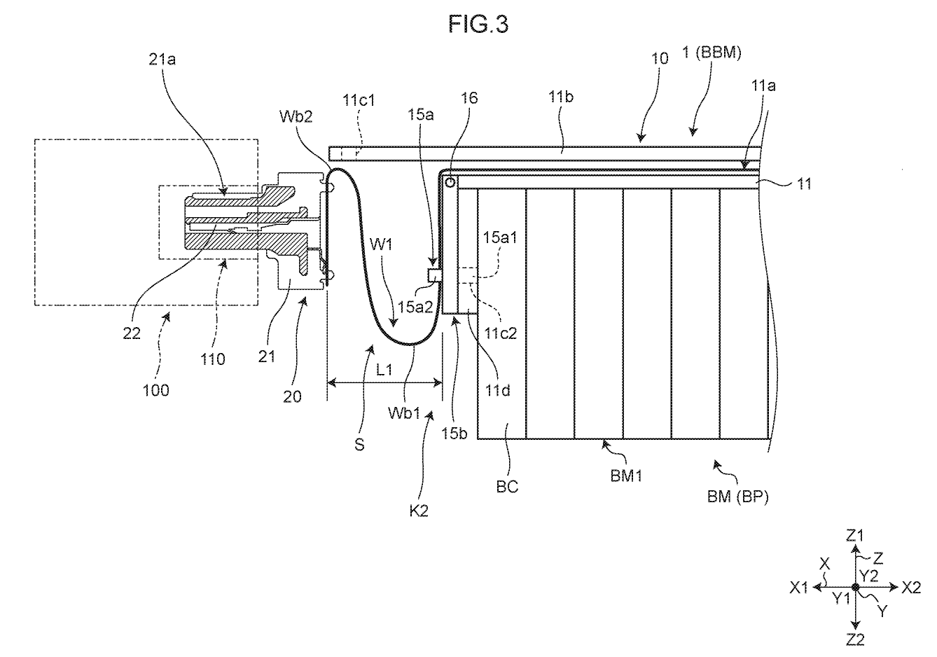

The busbar module BBM accommodates a plurality of busbars (not illustrated) electrically connected to a pair of electrodes (not illustrated) having a positive electrode terminal and a negative electrode terminal in each battery cell BC. The pair of electrodes of the plurality of battery cells BC are connected in parallel or in series by a plurality of busbars. The electrode terminal of each battery cell BC is electrically connected to the wiring material W via, for example, a voltage detection terminal (not illustrated). The voltage detection terminal is electrically connected to, for example, the bus bar, and detects a voltage between the electrode terminals. The wiring material W electrically connected to the voltage detection terminal is electrically connected to a monitoring device 100 (see FIG. 3) via the connector 20. The connector 20 is formed as a female connector and is fitted to a connector 110 (mating connector) of the monitoring device 100 formed as a male connector. The voltage of each battery cell BC is monitored by the monitoring device 100.

In the following description, a direction in which the connector 20 is fitted to the connector 110 of the monitoring device 100 is referred to as a fitting direction X, and two directions orthogonal to and intersecting the fitting direction X are referred to as a width direction Y and a height direction Z. The height direction Z is a direction perpendicular to an installation surface BM1 of the battery module BM. In the following description, one side in the fitting direction X is referred to as one side X1, and the other side is referred to as the other side X2. Similarly, a description will be made such that the width direction Y is defined as one side Y1 (the front side of the sheet in FIGS. 1 and 3) and the other side Y2 (the rear side of the sheet in FIGS. 1 and 3), and the height direction Z is defined as one side Z1 and the other side Z2.

Although not illustrated, the positive and negative electrode terminals of the battery cell BC are arranged, for example, on one side Z1 in the height direction Z of the battery cell BC, one electrode terminal is provided on one side Y1 in the width direction Y, and the other electrode terminal is provided on the other side Y2. The busbar module BBM extends along the fitting direction X and is assembled to one side Z1 of the battery module BM in the height direction Z. The wiring module 1 of the busbar module BBM includes the wiring module case 10. The wiring module case 10 has a wiring path 11a in which the wiring material W is provided. The wiring module case 10 has a case body 11 provided with the wiring path 11a and a hinge structure portion 15. The case body 11 of the wiring module case 10 is provided with a cover 11b that covers the wiring path 11a. The cover 11b is formed in a substantially flat plate shape with the plate surface facing the height direction Z. The cover 11b is fixed to the case body 11 by a fixing portion (not illustrated).

The wiring material W extends in the direction along the fitting direction X in the wiring path 11a, and is, for example, a flat wiring material such as a flexible printed circuit (FPC) or a flexible flat cable (FFC). When the wiring material W is an FPC, the wiring material W has a base film, a coverlay, and a conductive layer. The base film and the coverlay are flexible insulating resin layers. The conductive layer is sandwiched and protected by the base film and the coverlay. The conductive layer is, for example, a conductive metal foil, and has a plurality of circuit patterns electrically connected to the above-described bus bar (not illustrated) via a voltage detection terminal.

The case body 11 is formed in a substantially flat plate shape with a plate surface facing the height direction Z, extends in the fitting direction X, and is fixed to a surface on one side Z1 in the height direction Z in the battery module BM. The wiring path 11a through which the wiring material W is wired extends along the fitting direction X in the case body 11. The wiring path 11a is provided, for example, between the electrode terminals of the positive electrode and the negative electrode in the width direction Y of the plurality of battery cells BC, and is formed in a substantially recessed groove shape. In the present embodiment, the wiring material W serving as the flat wiring material is wired with the flat surface oriented in the height direction Z. The wiring material W is wired in the wiring path 11a along the direction (that is, the fitting direction X) in which the wiring path 11a extends. The wiring path 11a is provided with a boss or a hook-shaped claw portion, and the wiring material W is fixed to the wiring path 11a.

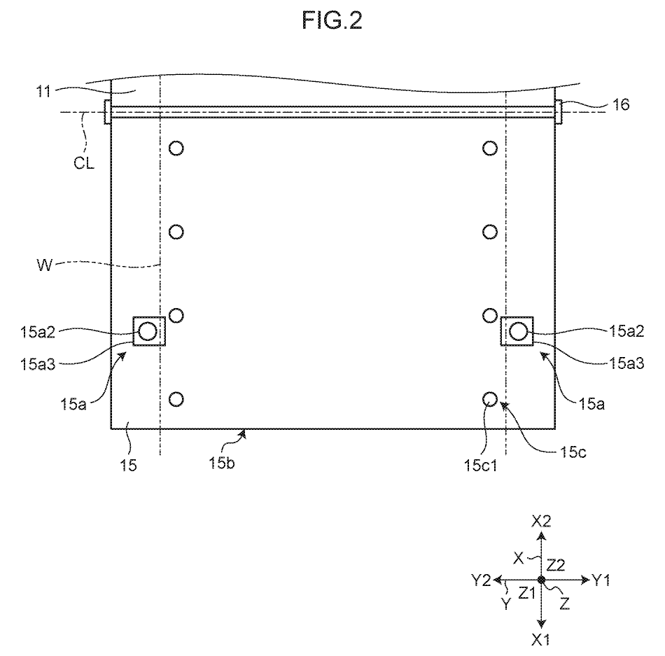

The hinge structure portion 15 is connected to an end of the case body 11 on one side X1 in the fitting direction X via a hinge 16. As illustrated in FIG. 2, the hinge structure portion 15 is formed such that the length in the width direction Y is substantially the same as the length in the width direction Y of the case body 11. The hinge structure portion 15 is rotatably provided around the axis CL of the hinge 16 between an extended position K1 (see FIG. 1) where the hinge structure portion extends from the case body 11 so as to protrude from the battery module BM and a bent position K2 (see FIG. 3) where the hinge structure portion approaches the battery module BM. The hinge structure portion 15 can be rotated so as to be bent from the extended position K1 toward the other side Z2 in the height direction Z to be the bent position K2.

The hinge structure portion 15 has a wiring material fixing portion 15c that fixes the wiring material W on one end side (one side X1 in the fitting direction X) from the wiring path 11a toward the connector 20. Specifically, the wiring material fixing portion 15c can be, for example, a plurality of bosses respectively engaged with a plurality of through-holes provided at the edge of the wiring material W, a plurality of hook-shaped claw portions engaged with the edge of the wiring material W, or the like. FIG. 2 illustrates a plurality of bosses 15c1 as the wiring material fixing portion 15c. The wiring material fixing portion 15c is provided on a surface of the hinge structure portion 15 on the cover 11b side (surface on one side Z1 in the height direction Z) when the hinge structure portion 15 is located at the extended position K1. That is, a part of the wiring material W extending from the end of the wiring path 11a on the one side X1 in the fitting direction X to the one side X1 is fixed to the wiring material fixing portion 15c.

In addition, the hinge structure portion 15 is provided with a hinge structure portion-side locking portion 15a. In the present embodiment, as illustrated in FIG. 2, the hinge structure portion-side locking portions 15a are provided at two positions facing each other across the wiring material W in the width direction Y. On the other hand, as illustrated in FIG. 1, the case body 11 has a first locking portion 11c1 to which the hinge structure portion-side locking portion 15a is locked at the extended position K1 of the hinge structure portion 15, and a second locking portion 11c2 to which the hinge structure portion-side locking portion 15a is locked at the bent position K2 of the hinge structure portion 15. In the present embodiment, the first locking portion 11c1 is provided on the cover 11b. The second locking portion 11c2 is provided on the plate-shaped member 11d. Here, the plate-shaped member 11d is a battery cell BC provided at an end on one side X1 in the fitting direction X, and is provided on a side surface on one side X1 in the fitting direction X in the battery cell BC. The plate-shaped member 11d can also be, for example, an end plate in the battery module BM.

The hinge structure portion-side locking portion 15a can be provided with, for example, a first protrusion 15a1 protruding from a surface on one side Z1 in the height direction Z of the substantially plate-shaped hinge structure portion 15 and a second protrusion 15a2 protruding from a surface on the other side Z2 when the hinge structure portion 15 is located at the extended position K1. The first protrusion 15a1 is formed in, for example, a pin shape so as to be press-fitted into the first locking portion 11c1 formed in a concave shape. In addition, the second protrusion 15a2 is formed in, for example, a pin shape so as to be press-fitted into the second locking portion 11c2 formed in a concave shape. As illustrated in FIG. 2, the hinge structure portion-side locking portion 15a is provided with a claw-shaped locking portion 15a3 protruding in a claw shape toward the wiring material W. For example, when the hinge structure portion 15 is located at the extended position K1, the claw-shaped locking portion 15a3 can be provided between the second protrusion 15a2 and the surface of the hinge structure portion 15 on the other side Z2 in the height direction Z. The claw-shaped locking portion 15a3 can lock the wiring material W to the edge of the wiring material W to fix the wiring material W to the hinge structure portion-side locking portion 15a.

As illustrated in FIG. 1, when the hinge structure portion 15 is located at the extended position K1, the wiring material W extends outward from the distal end 15b of the hinge structure portion 15. Here, the connector 20 has a housing 21 constituting a casing of the connector 20 and a plurality of terminals 22. One end of the wiring material W is fixed to the housing 21 of the connector 20. The housing 21 of the connector 20 is formed in a substantially rectangular box shape that is elongated in the width direction Y. One side X1 of the housing 21 in the fitting direction X is formed in a substantially rectangular tubular shape elongated in the width direction Y, and is a terminal holding portion 21a that holds the plurality of terminals 22. In the terminal holding portion 21a, the plurality of terminals 22 are arranged and held in the width direction Y.

Here, the connector 110 of the monitoring device 100 illustrated in FIG. 3 is provided with a terminal (not illustrated) serving as a male terminal. A terminal of the connector 110 is held by a substantially rectangular tubular hood portion (not illustrated) elongated in the width direction Y formed in the connector 110. The terminal holding portion 21aof the connector 20 is inserted into the hood portion of the connector 110 of the monitoring device 100 along the fitting direction X. When the terminal holding portion 21ais inserted into the hood portion of the connector 110, the terminal 22 of the connector 20 serving as the female terminal and the terminal of the connector 110 of the monitoring device 100 serving as the male terminal are fitted and electrically connected.

One end of the wiring material W (an end of the wiring material W on one side X1 in the fitting direction X) is fixed to the other side X2 in the fitting direction X of the housing 21 of the connector 20. The wiring material W is fixed to the housing 21 by, for example, a fixing member such as a peg for fixing the wiring material W to the housing 21. By fixing the wiring material W to the housing 21 of the connector 20, the plurality of terminals 22 of the connector 20 are electrically connected to the wiring material W.

The wiring material W is fixed from one side Z1 in the height direction Z of the housing 21 of the connector 20. Therefore, the wiring material W extends on one side Z1 in the height direction Z of the housing 21.

As described above, the connector 20 is fitted to the connector 110 of the monitoring device 100. The wiring material W has a margin in the length from the distal end 15b of the hinge structure portion 15 to the connector 20 at the extended position K1 so that the connector 20 can be reliably fitted to the connector 110 of the monitoring device 100. That is, as illustrated in FIG. 3, the wiring material W has an extra length portion W1 (see also FIG. 1) which is excessively longer than the distance L1 from the distal end 15b of the hinge structure portion 15 to the connector 110 in a state where the connector 20 is fitted to the connector 110 of the monitoring device 100.

The fitting between the connector 20 and the connector 110 of the monitoring device 100 can be performed in a state where the hinge structure portion 15 is in the extended position K1 (see FIG. 1). After the connector 20 and the connector 110 of the monitoring device 100 are fitted to each other, the extra length portion W1 is folded by setting the hinge structure portion 15 to the bent position K2. That is, as illustrated in FIG. 3, the hinge structure portion 15 forms a folding space portion S for accommodating the wiring material W (extra length portion W1) in which one end side from the wiring material fixing portion 15c (that is, the distal end 15b of the hinge structure portion 15) toward the connector 20 is folded with respect to the connector 20 at the bent position K2. As a way of folding the extra length portion W1 of the wiring material W in the folding space portion S, for example, a first bent portion Wb1 bent so as to extend toward one side Z1 in the height direction Z is formed in the extra length portion W1 of the wiring material W extending from the distal end 15b (or the wiring material fixing portion 15c on the distal end 15b side, see FIG. 2.) of the hinge structure portion 15 to the other side Z2 in the height direction Z. The extra length portion W1 of the wiring material W bent at the first bent portion Wb1 is formed with a second bent portion Wb2 extending by a predetermined length on one side Z1 in the height direction Z and bent to the other side Z2 in the height direction Z before being fixed to the housing 21 of the connector 20. The wiring material W bent at the second bent portion Wb2 is fixed to the housing 21 of the connector 20. In this way, the extra length portion W1 of the wiring material W can be reliably folded and arranged.

In the present embodiment, at the bent position K2, the wiring material W extending from the distal end 15b (specifically, for example, the wiring material fixing portion 15c on the distal end 15b side) of the hinge structure portion 15 extends to the other side Z2 in the height direction Z. On the other hand, the wiring material W fixed to the housing 21 of the connector 20 extends on one side Z1 in the height direction Z. As described above, the positional relationship in the height direction Z between the hinge structure portion 15 at the bent position K2 and the connector 20 fitted to the connector 110 of the monitoring device 100 is set such that the folding space portion S is formed.

The wiring module 1 described above includes the wiring material W which is electrically connected to the electrode terminals of the battery cells BC constituting the battery module BM, the wiring module case 10 which has the wiring path 11a provided with the wiring material W, and the connector 20 which has the housing 21 for fixing one end of the wiring material W. The wiring module case 10 has the case body 11 which is provided with the wiring path 11a and the hinge structure portion 15 which is connected to the case body 11 on the connector 20 side of the case body 11 via the hinge 16, is rotatably provided around the axis CL of the hinge 16 between the extended position K1 extending from the case body 11 so as to protrude from the battery module BM and the bent position K2 approaching the battery module BM, and has the wiring material fixing portion 15c for fixing the wiring material W on one end side from the wiring path 11a toward the connector 20.

As a result, after the connector 20 to which the wiring material W is fixed is fitted to the connector 110 of the monitoring device 100 which is the mating connector, the extra length portion W1 is folded along the hinge structure portion 15 by rotating the hinge structure portion 15 from the extended position K1 to the bent position K2. In this way, the extra length portion W1 of the wiring material W can be appropriately arranged. When the extra length portion W1 is appropriately arranged, the wiring material W is protected, and interference between members and devices around the battery pack BP (battery module BM) such as a cover of the battery pack BP and the extra length portion W1 of the wiring material W is reduced. In addition, since the extra length portion W1 can be folded by the rotation operation of the hinge structure portion 15 that is easy to work, the number of work steps for folding the extra length portion W1 can be reduced.

In addition, at the bent position K2, the hinge structure portion 15 forms the folding space portion S for accommodating the wiring material W in which one end side from the wiring material fixing portion 15c toward the connector 20 is folded with respect to the connector 20. As a result, since the extra length portion W1 of the folded wiring material W is arranged in the folding space portion S, disconnection due to interference with peripheral devices and members is further reduced, and the wiring material W can be protected.

In addition, the hinge structure portion 15 has the hinge structure portion-side locking portion 15a, and the case body 11 has the first locking portion 11c1 to which the hinge structure portion-side locking portion 15a is locked at the extended position K1 of the hinge structure portion 15 and the second locking portion 11c2 to which the hinge structure portion-side locking portion 15a is locked at the bent position K2 of the hinge structure portion 15. As a result, the hinge structure portion 15 can be fixed when the connector 20 is fitted to the connector 110 of the monitoring device 100, and workability can be improved. Furthermore, since the hinge structure portion 15 can be fixed after the fitting of the connector 20, for example, in a case where the wiring module 1 is assembled to the battery pack BP mounted on the vehicle, it is possible to reduce the possibility that the hinge structure portion 15 having received vibration is unintentionally located at the extended position K1 to return the folded extra length portion W1 to the original position. In particular, when the FPC having a strong repulsive force is adopted as the wiring material W, the hinge structure portion 15 can appropriately maintain the bent position K2 by locking the hinge structure portion-side locking portion 15a and the second locking portion 11c2.

In addition, the wiring module according to the embodiment of the present invention described above is not limited to the embodiment described above, and various modifications can be made within the scope described in the claims.

In the above description, the first locking portion 11c1 is provided on the cover 11b, and the second locking portion 11c2 is provided on the plate-shaped member 11d. However, as long as the either locking portion can be locked to the hinge structure portion-side locking portion 15a of the hinge structure portion 15, the second locking portion 11c2 can be provided at another portion. In addition, the fitting structure of the first protrusion 15a1 and the second protrusion 15a2 of the hinge structure portion-side locking portion 15a and the first locking portion 11c1 and the second locking portion 11c2 is not limited to press-fitting, and other locking structures can be adopted.

The wiring module according to the present embodiment may be configured by appropriately combining the components of the embodiment and the modifications described above.

The wiring module according to the present embodiment has an effect that the extra length portion of the wiring material can be appropriately arranged.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A wiring module comprising:
a wiring material that is electrically connected to an electrode terminal of a battery cell constituting a battery module;
a wiring module case that has a wiring path provided with the wiring material; and
a connector that has a housing to which one end of the wiring material is fixed, wherein
the wiring module case has a case body that is provided with the wiring path, and a hinge structure portion that is connected to the case body on the connector side of the case body via a hinge, is rotatably provided around an axis of the hinge between an extended position extending from the case body so as to protrude from the battery module and a bent position approaching the battery module, and has a wiring material fixing portion for fixing the wiring material on the one end side from the wiring path toward the connector.

2. The wiring module according to claim 1, wherein
the hinge structure portion forms a folding space portion for accommodating the wiring material in which the one end side from the wiring material fixing portion toward the connector is folded between the hinge structure portion and the connector at the bent position.

3. The wiring module according to claim 1, wherein
the hinge structure portion has a hinge structure portion-side locking portion, and
the case body has a first locking portion to which the hinge structure portion-side locking portion is locked at the extended position of the hinge structure portion and a second locking portion to which the hinge structure portion-side locking portion is locked at the bent position of the hinge structure portion.

4. The wiring module according to claim 2, wherein
the hinge structure portion has a hinge structure portion-side locking portion, and
the case body has a first locking portion to which the hinge structure portion-side locking portion is locked at the extended position of the hinge structure portion and a second locking portion to which the hinge structure portion-side locking portion is locked at the bent position of the hinge structure portion.
